(19) United States
(12) Patent Application Publication
(10) Pub. No.: US 2026/0322433 A1
(43) Pub. Date: Oct. 15, 2026

(54) CAUSAL ENCODING OF CHANNEL STATE INFORMATION

(71) Applicant: Telefonaktiebolaget LM Ericsson (publ), Stockholm (SE)

(72) Inventors: Serene BANERJEE, Bangalore (IN); Lackis ELEFTHERIADIS, Stockholm (SE); Hamed FARHADI, Stockholm (SE); Athanasios KARAPANTELAKIS, Stockholm (SE); Karthik R M, Chennai (IN); Vandita SINGH, Stockholm (SE)

(73) Assignee: Telefonaktiebolaget LM Ericsson (publ), Stockholm (SE)

(21) Appl. No.: 19/106,508

(22) PCT Filed: Aug. 1, 2023
(86) PCT No.: PCT/SE2023/050763

§ 371 Date: Feb. 25, 2025

(30) Foreign Application Priority Data
Sep. 1, 2022 (GR) 20220100721

(51) Int. Cl. H04B 7/0417; H04B 7/024; H04B 7/06; H04B 17/345; H04B 17/391; H04W 24/10

(52) U.S. Cl. CPC H04B 7/0417; H04B 7/024; H04B 17/345; H04B 17/3913; H04W 24/10; H04B 7/0626; H04B 7/0658

(57) ABSTRACT

A computer-implemented method is provided performed by a first computing device for causal encoding of channel state information, CSI, is provided. The method includes obtaining an indication of incorrect reporting of CSI; retrieving parameter data; obtaining a measurement of CSI data; and activating a machine learning, ML, model for CSI reporting. The ML model including causal relationships among the parameter data and the measurement of CSI data. The method further includes encoding the measurement of CSI data to obtain encoded CSI measurement data; applying the ML model to the parameter data and the encoded CSI measurement data to obtain an adapted CSI measurement data; and transmitting the adapted CSI measurement data to a second computing device. A computer implemented, method performed by a second computing device, and related methods and apparatus are also provided.

### TECHNICAL FIELD

The present disclosure relates generally to computer-implemented methods performed by a first computing device for causal encoding of channel state information (CSI), and related methods and apparatuses.

### BACKGROUND

For potential gains in a telecommunication system, CSI can be sent between a base station (BS) and a user equipment (UE). For example, potential gains may be realized in a massive multi-input-multi-output (MIMO) system; handovers with other antenna types; in a frequency division duplexing (FDD) system; a point to point system for obtaining downlink CSI from uplink; distributed-MINO (D-MIMO) for obtaining CSI from a subset of access points for use with other remaining access points, etc. Overhead of bidirectional signaling on channel state estimation, however, may sometimes offset benefits of sending CSI. Some approaches may include compression of CSI feedback using autoencoders. However, such approaches may lack domain adaption based on, e.g., changes in an environment. See e.g., C. K Wen, W-T Shih, and S. Jin, “Deep Learning for Massive MIMO CSI Feedback”, IEEE Wireless Communication Letters, vol. 7, no. 5, October 2018, https://github.com/sydney222/Python_CsiNet (“Wen”); Y. Sun, W. Xu, L. Liang, N. Wang, G. Y. Li, X. You, “A Lightweight Deep Network for Efficient CSI Feedback in Massive MIMO Systems”, arXiv:2105.10283, 2021 (“Sun”). Due to, e.g. parameters related to BS vendor's or UE vendors' equipment, there may be distributional shifts between training and test data such that a machine learning (ML) model involved with the CSI feedback may be executed on an environment that is different than an environment included in the ML model training.

Addressing data sharing and ML model sharing based on, e.g., feasibility and/or privacy constraints, may be lacking. Additionally, excessive reference signaling may increase power consumption. For example, from a mobile network side, reference signals activating a power amplifier (PA) may not allow the PA to go to a sleep state.

### SUMMARY

There currently exist certain challenges. While some approaches may include variational graph autoencoders, such approaches may not address CSI, domain adaption, and/or power savings. A method may be lacking for causal encoding of CSI using an autoencoder that can adapt to changes in data distribution and, thus, conserve energy.

Certain aspects of the disclosure and their embodiments may provide solutions to these or other challenges.

In various embodiments of the present disclosure, a computer-implemented method performed by a first computing device for causal encoding of CSI is provided. The method includes obtaining an indication of incorrect reporting of CSI; retrieving parameter data including a plurality of specific parameters and a plurality of general parameters; obtaining a measurement of CSI data; and activating a machine learning (ML) model for CSI reporting. The ML model includes causal relationships among the parameter data and the measurement of CSI data. The method further includes encoding the measurement of CSI data to obtain encoded CSI measurement data; applying the ML model to the parameter data and the encoded CSI measurement data to obtain an adapted CSI measurement data; and transmitting the adapted CSI measurement data to a second computing device.

In other embodiments, a computer-implemented method performed by a second computing device for decoding causally encoded CSI is provided. The method includes receiving an adapted CSI data from a first computing device, where the adapted CSI data was output from a ML model for CSI reporting including causal relationships among parameter data comprising a plurality of specific parameters and a plurality of general parameters and a measurement of CSI data. The method further includes decoding the adapted CSI measurement data to obtain decoded CSI; and using the decoded CSI for a resource allocation.

In other embodiments, a computer-implemented method performed by a second computing device for causal encoding and decoding of CSI is provided. The method includes detecting an incorrect reporting of CSI for a first computing device; retrieving parameter data comprising a plurality of specific parameters and a plurality of general parameters; and obtaining a measurement of CSI data from the first computing device. The method further includes activating a ML model for CSI reporting. The ML model includes causal relationships among the parameter data and the measured CSI data. The method further includes encoding the measurement CSI data to obtain encoded CSI measurement data; and applying the ML model to the parameter data and the encoded CSI measurement data to obtain an adapted CSI measurement data.

In other embodiments, a first computing device is provided. The first computing device is configured for causal encoding of CSI. The first computing device includes processing circuitry; and at least one memory coupled with the processing circuitry. The memory includes instructions that when executed by the processing circuitry causes the first computing device to perform operations. The operations include to obtain an indication of incorrect reporting of CSI; retrieve parameter data including a plurality of specific parameters and a plurality of general parameters; obtain a measurement of CSI data; and activate a ML model for CSI reporting. The ML model includes causal relationships among the parameter data and the measurement of CSI data. The operations further include to encode the measurement of CSI data to obtain encoded CSI measurement data; apply the ML model to the parameter data and the encoded CSI measurement data to obtain an adapted CSI measurement data; and transmit the adapted CSI measurement data to a second computing device.

In other embodiments, a first computing device is provided that is configured for causal encoding of CSI. The first computing device is adapted to perform operations. The operations include to obtain an indication of incorrect reporting of CSI; retrieve parameter data including a plurality of specific parameters and a plurality of general parameters; obtain a measurement of CSI data; and activate a ML model for CSI reporting. The ML model includes causal relationships among the parameter data and the measurement of CSI data. The operations further include to encode the measurement of CSI data to obtain encoded CSI measurement data; apply the ML model to the parameter data and the encoded CSI measurement data to obtain an adapted CSI measurement data; and transmit the adapted CSI measurement data to a second computing device.

In other embodiments, a computer program comprising program code is provided to be executed by processing circuitry of a first computing device configured for causal encoding of CSI. Execution of the program code causes the first computing device to perform operations. The operations include to obtain an indication of incorrect reporting of CSI; retrieve parameter data including a plurality of specific parameters and a plurality of general parameters; obtain a measurement of CSI data; and activate a ML model for CSI reporting. The ML model includes causal relationships among the parameter data and the measurement of CSI data. The operations further include to encode the measurement of CSI data to obtain encoded CSI measurement data; apply the ML model to the parameter data and the encoded CSI measurement data to obtain an adapted CSI measurement data; and transmit the adapted CSI measurement data to a second computing device.

In other embodiments, a computer program product is provided comprising a non-transitory storage medium including program code to be executed by processing circuitry of a first computing device configured for causal encoding of CSI. Execution of the program code causes the first computing device to perform operations. The operations include to obtain an indication of incorrect reporting of CSI; retrieve parameter data including a plurality of specific parameters and a plurality of general parameters; obtain a measurement of CSI data; and activate a ML model for CSI reporting. The ML model includes causal relationships among the parameter data and the measurement of CSI data. The operations further include to encode the measurement of CSI data to obtain encoded CSI measurement data; apply the ML model to the parameter data and the encoded CSI measurement data to obtain an adapted CSI measurement data; and transmit the adapted CSI measurement data to a second computing device.

In other embodiments, a second computing device is provided. The second computing device is configured for decoding causally encoded CSI. The second computing device includes processing circuitry; and at least one memory coupled with the processing circuitry. The memory includes instructions that when executed by the processing circuitry causes the second computing device to perform operations. The operations include to receive an adapted CSI data from a first computing device, where the adapted CSI data was output from a ML model for CSI reporting including causal relationships among parameter data comprising a plurality of specific parameters and a plurality of general parameters and a measurement of CSI data. The operations further include to decode the adapted CSI measurement data to obtain decoded CSI; and use the decoded CSI for a resource allocation.

In other embodiments, a second computing device is provided that is configured for decoding causally encoded CSI. The second computing device is adapted to perform operations. The operations include to receive an adapted CSI data from a first computing device, where the adapted CSI data was output from a ML model for CSI reporting including causal relationships among parameter data comprising a plurality of specific parameters and a plurality of general parameters and a measurement of CSI data. The operations further include to decode the adapted CSI measurement data to obtain decoded CSI; and use the decoded CSI for a resource allocation.

In other embodiments, a computer program comprising program code is provided to be executed by processing circuitry of a second computing device configured for decoding causally encoded CSI. Execution of the program code causes the second computing device to perform operations. The operations include to receive an adapted CSI data from a first computing device, where the adapted CSI data was output from a ML model for CSI reporting including causal relationships among parameter data comprising a plurality of specific parameters and a plurality of general parameters and a measurement of CSI data. The operations further include to decode the adapted CSI measurement data to obtain decoded CSI; and use the decoded CSI for a resource allocation.

In other embodiments, a computer program product is provided including a non-transitory storage medium including program code to be executed by processing circuitry of a second computing device configured for decoding causally encoded CSI. Execution of the program code causes the second computing device to perform operations. The operations include to receive an adapted CSI data from a first computing device, where the adapted CSI data was output from a ML model for CSI reporting including causal relationships among parameter data comprising a plurality of specific parameters and a plurality of general parameters and a measurement of CSI data. The operations further include to decode the adapted CSI measurement data to obtain decoded CSI; and use the decoded CSI for a resource allocation.

In other embodiments, a second computing device is provided. The second computing device is configured for causal encoding and decoding of CSI. The second computing device includes processing circuitry; and at least one memory coupled with the processing circuitry. The memory includes instructions that when executed by the processing circuitry causes the second computing device to perform operations. The operations include to detect an incorrect reporting of CSI for a first computing device; retrieve parameter data comprising a plurality of specific parameters and a plurality of general parameters; and obtain a measurement of CSI data from the first computing device. The operations further include to activate a ML model for CSI reporting. The ML model includes causal relationships among the parameter data and the measured CSI data. The operations further include to encode the measurement CSI data to obtain encoded CSI measurement data; and apply the ML model to the parameter data and the encoded CSI measurement data to obtain an adapted CSI measurement data.

In other embodiments, a second computing device is provided that is configured for causal encoding and decoding of CSI. The second computing device is adapted to perform operations. The operations include to detect an incorrect reporting of CSI for a first computing device; retrieve parameter data comprising a plurality of specific parameters and a plurality of general parameters; and obtain a measurement of CSI data from the first computing device. The operations further include to activate a ML model for CSI reporting. The ML model includes causal relationships among the parameter data and the measured CSI data. The operations further include to encode the measurement CSI data to obtain encoded CSI measurement data; and apply the ML model to the parameter data and the encoded CSI measurement data to obtain an adapted CSI measurement data.

In other embodiments, a computer program comprising program code is provided to be executed by processing circuitry of a second computing device configured for causal encoding and decoding of CSI. Execution of the program code causes the second computing device to perform operations. The operations include to detect an incorrect reporting of CSI for a first computing device; retrieve parameter data comprising a plurality of specific parameters and a plurality of general parameters; and obtain a measurement of CSI data from the first computing device. The operations further include to activate a ML model for CSI reporting. The ML model includes causal relationships among the parameter data and the measured CSI data. The operations further include to encode the measurement CSI data to obtain encoded CSI measurement data; and apply the ML model to the parameter data and the encoded CSI measurement data to obtain an adapted CSI measurement data.

In other embodiments, a computer program product is provided including a non-transitory storage medium including program code to be executed by processing circuitry of a second computing device configured for causal encoding and decoding of CSI. Execution of the program code causes the second computing device to perform operations. The operations include to detect an incorrect reporting of CSI for a first computing device; retrieve parameter data comprising a plurality of specific parameters and a plurality of general parameters; and obtain a measurement of CSI data from the first computing device. The operations further include to activate a ML model for CSI reporting. The ML model includes causal relationships among the parameter data and the measured CSI data. The operations further include to encode the measurement CSI data to obtain encoded CSI measurement data; and apply the ML model to the parameter data and the encoded CSI measurement data to obtain an adapted CSI measurement data.

Certain embodiments may provide one or more of the following technical advantages. Based on the inclusion of causal aware CSI encoding, domain adaption and/or power savings may be achieved.

### BRIEF DESCRIPTION OF DRAWINGS

The accompanying drawings, which are included to provide a further understanding of the disclosure and are incorporated in and constitute a part of this application, illustrate certain non-limiting embodiments of inventive concepts. In the drawings:

FIG. 1 is a schematic diagram illustrating an overview of operations in accordance with some embodiments of the present disclosure;

FIG. 2 is a signalling diagram illustrating operations performed by a first computing device (e.g., a UE) for causal encoding of CSI in accordance with the present disclosure;

FIG. 3 is a signalling diagram illustrating operations performed by a second computing device (e.g., a gNB) for causal encoding and/or decoding of CSI in accordance with some embodiments of the present disclosure;

FIG. 4 is a block diagram illustrating a causally aware CSI encoding system in accordance with some embodiments of the present disclosure;

FIG. 5 is a block diagram of an encoder that captures causal relationships in accordance with some embodiments of the present disclosure;

FIG. 6 is images of sample CSI data from an indoor and an outdoor setting;

FIGS. 7 and 8 are train and test loss plots, respectively, for a simulation of an example embodiment of the present disclosure;

FIGS. 9A-D are images of sample reconstructions from a variational autoencoder (VAE) of the simulation of the example embodiment;

FIGS. 10A-F are images of results of VAE reconstruction where causal parameters were changed in the simulation of the example embodiment;

FIG. 11 is an original CSI image and a CSI image reconstructed in the simulation of the example embodiment;

FIG. 12 is an original CSI image and a CSI image reconstructed with intervention on scale in the simulation of the example embodiment;

FIG. 13 is an original CSI image and a CSI counterfactual image reconstructed in the simulation of the example embodiment;

FIG. 14 is a flow chart of operations of a first computing device in accordance with some embodiments of the present disclosure;

FIGS. 15 and 16 is a flow chart of operations of a second computing device in accordance with some embodiments of the present disclosure;

FIG. 17 is a block diagram of a network in accordance with some embodiments;

FIG. 18 is a block diagram of a computing device in accordance with some embodiments of the present disclosure;

FIG. 19 is a block diagram of a computing device in accordance with some embodiments of the present disclosure; and

FIG. 20 is a block diagram of a virtualization environment in accordance with some embodiments of the present disclosure.

### DETAILED DESCRIPTION

Inventive concepts will now be described more fully hereinafter with reference to the accompanying drawings, in which examples of embodiments of inventive concepts are shown. Inventive concepts may, however, be embodied in many different forms and should not be construed as limited to the embodiments set forth herein. Rather, these embodiments are provided so that this disclosure will be thorough and complete, and will fully convey the scope of present inventive concepts to those skilled in the art. It should also be noted that these embodiments are not mutually exclusive. Components from one embodiment may be tacitly assumed to be present/used in another embodiment.

The following description presents various embodiments of the disclosed subject matter. These embodiments are presented as teaching examples and are not to be construed as limiting the scope of the disclosed subject matter. For example, certain details of the described embodiments may be modified, omitted, or expanded upon without departing from the scope of the described subject matter.

As used herein, the term “first computing device” refers to equipment capable, configured, arranged, and/or operable for causal encoding of CSI. As discussed further herein, examples of first computing devices include, but are not limited to, a computer, a decentralized edge device, a decentralized edge server, a distributed collection of access points (e.g., base stations) that cooperate via a central processing unit (CPU), and a UE. The UE may include, e.g., a smart phone, mobile phone, cell phone, voice over IP (VoIP) phone, wireless local loop phone, desktop computer, personal digital assistant (PDA), wireless cameras, gaming console or device, music storage device, playback appliance, wearable terminal device, wireless endpoint, mobile station, tablet, laptop, laptop-embedded equipment (LEE), laptop-mounted equipment (LME), smart device, wireless customer-premise equipment (CPE), vehicle-mounted or vehicle embedded/integrated wireless device, etc. Other examples include any UE identified by the 3rd Generation Partnership Project (3GPP), including a narrow band internet of things (NB-IoT) UE, a machine type communication (MTC) UE, and/or an enhanced MTC (eMTC) UE. For example, in D-MIMO, the first computing device may include a distributed collection of access points (APs) that cooperate via a CPU, and channel estimation can be done at an AP or centrally at the CPU where channel estimates from all APs in the distributed collection can be combined for precoding or receive combining. Further, a machine learning (ML) model may be distributed at different ones of the APs and one central entity can combine them.

As used herein, the term “second computing device” refers to equipment capable, configured, arranged, and/or operable for causal encoding and/or decoding of CSI. As discussed further herein, examples of second computing devices include, but are not limited to, a computer, a decentralized edge device, a decentralized edge server, a cloud node, a cloud server, and centralized or distributed APs (e.g., base stations) in a radio access network (RAN) (e.g., GNodeBs (gNBs), evolved NodeBs (eNBs), core network nodes, access points (Aps) (e.g., radio access points) etc.).

As used herein, the term “parameter data” refers to parameter data provided by a vendor (e.g., a UE vendor, a gNB vendor, etc.) and includes, without limitation, vendor-specific parameter data and general/universal parameter data as discussed further herein.

As discussed above, there currently exist certain challenges. Some approaches using autoencoders may not be able to adapt to changes in parameter data due to vendor differences and/or data drifts within the same vendor for CSI compression. Moreover, existing approaches may lack applying causal encoding for CSI compression that can adapt to a different domain and/or save power.

Certain aspects of the disclosure and their embodiments may provide solutions to these or other challenges. In some embodiments, operations are provided that include causally aware CSI encoding that can adapt to changes in parameter data distribution, and perform domain adaptation by applying a ML model to received data (e.g. by applying a causal layer in neural network).

In some embodiments, the operations further include creation of a ML model of underlying constraints that generate observational data including CSI data. The ML model may be a structural causal model (SCM), where the ML model captures a cause-and-effect relationships between an observational or endogenous variable from the CSI data and an unobserved or exogenous variable(s) from the parameter data (e.g. a UE speed, frequency, etc., discussed further herein).

In some embodiments, a causal graph is represented by a directed acyclic graph(s) (DAG(s)), where nodes (e.g., vertices) correspond to the endogenous variables, and directed edges account for a causal parent-child relationship. A endogenous variable can be an input vector of a channel H matrix, and an exogenous variable(s) can include the parameter data (e.g., power thresholds, channel quality indicator, etc. discussed further herein).

Certain embodiments may provide one or more of the following technical advantages. Inclusion of causally aware encoding may circumvent a need for retraining a ML model for a data distribution or environmental change. Moreover, only one ML model may need to be stored on the network side (e.g., at a BS) and a device side (e.g., at a UE). As a consequence, power consumption and bandwidth may be reduced based on a decrease of signaling overhead.

Various embodiments of the present disclosure are directed to operations performed by a first computing device (e.g., a UE) and/or a second computing device (e.g., a BS such as a gNB) for causality-aware encoding of CSI, which may result in improved domain adaptability and/or explainability. For example, between different UE or gNB vendors during training and/or deployment time, there can be different parameter data such as thresholds and/or different environmental operational conditions (e.g., UE mobility such as speed and direction of movement in relation to a gNB, line of sight or non-line of sight propagation, channel richness, channel correlations, power usage of the UE and/or the gNB, etc.). Another example of parameter data that may affect CSI reports is power constraints, such as adjustments of a power amplifier, discussed further herein.

According to some embodiments, a ML model performs operations to model underlying constraints that generate observational data including CSI. The ML model may be a structural causal models (SCM). The ML model (e.g., SCM) captures cause-and-effect relationships (e.g., dependencies of CSI on UE speed, CSI dependencies on frequency, etc.) and can also address hidden confounders. Thus, as a fundamental causal structure is captured, domain adaptation can be obtained by matching a causal layer (e.g., in a neural network based SCM). As a consequence, the operations may be scalable.

Various embodiments of the present disclosure are directed to operations for a single-cell downlink massive MIMO system with Nₜ>>1 transmit antennas at a second computing device (e.g., a base station) and a single receiver antenna on the first computing device side (e.g., on a UE side). An orthogonal frequency division multiplexing (OFDM) system can include N_{c} subcarriers and, thus, a received signal at the nth subcarrier can be given by:

$${y}_{n} = {h}_{n}^{H} {v}_{n} {x}_{n} + {z}_{n}$$

where hₙ, vₙ, xₙ and zₙ denote a channel vector, precoding vector, data-bearing symbol, and additive noise of the n^{th} subcarrier, respectively. In this formulation, the second computing device (e.g., BS) expects the first computing device (e.g., UE) to return an estimate of a channel H matrix via feedback links.

Since overhead can be costly, some approaches may implement an autoencoder. See e.g., Wen; Sun. An encoder may take a channel matrix H as an input, and reconstruct the channel matrix Ĥ. An autoencoder may be trained in an unsupervised learning setting, where a set of parameters is updated by an adaptive moment estimation (ADAM) algorithm. A loss function may be mean square error (MSE), calculated as an average over all the training samples. An ADAM optimizer and MSE are examples and other optimization and error calculation methods can be used.

Various embodiments of the present disclosure are directed to operations performed by a first computing device and/or a second computing device that augment an autoencoder based on use of a ML model. The ML model may model observational or endogenous variables, such as CSI H, as a function of exogenous (unobserved) variables from parameter data, using structural causal equations or functional causal models (FCMs).

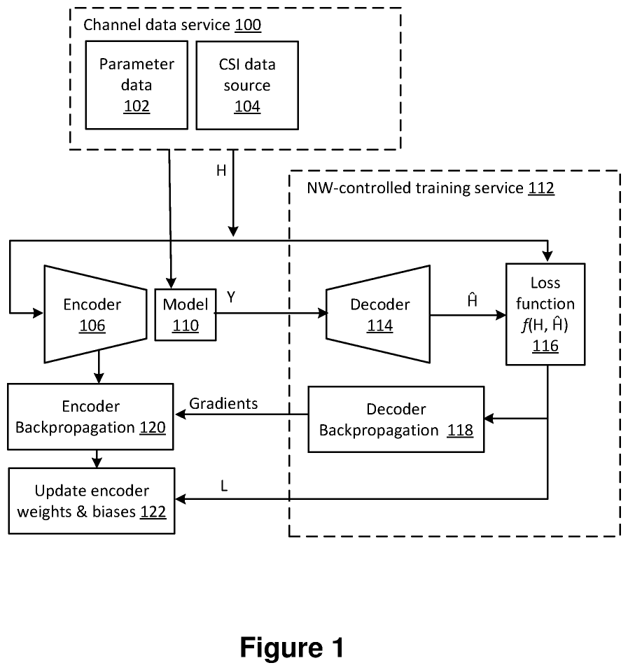

FIG. 1 is a schematic diagram illustrating an overview of operations in accordance with some embodiments of the present disclosure. As illustrated, parameter data 102 and CSI data H from a channel data source 104 may be included in a channel data service 100. The CSI data H 104 is provided to encoder 106 and loss function 116. During training, a ML model 110 (e.g., a SCM as illustrated) is built that models how data distribution changes with changes in the parameter data 102 that are provided to the ML model 110. The ML model 110 captures causal relationships among the parameter data and the measured CSI data. ML model 110, therefore, can be vendor agnostic based on inclusion of the parameter data, which can take care of changes in the autoencoded output of encoder 106 that are specific to a parameter data change.

ML model 110 can be trained using the same loss function 116 as decoder 114. As input data, encoder 106 uses CSI channel data H, e.g., available from channel data service 100. The CSI channel data H can include features indicating an estimated channel quality. As discussed further herein, the CSI channel data H can be a three-dimensional tensor where dimensions correspond to a second computing device's (e.g., a base station such as a gNB) transmission antenna ports, a first computing device's (e.g., a UE) receive antenna ports, and frequency (either divided in subcarriers or subbands). Encoder 106 outputs a temporary latent space representation, Yₜₑₘₚ which is transformed by ML model 110 to a latent space that is input to decoder 114. In addition to Yₜₑₘₚ, ML model 110 uses parameter data 102 to transform Yₜₑₘₚ to Y.

During training, backpropagation is performed with decoder backpropagation 118 and encoder backpropagation 120 using the loss function 116. Loss function 116 is provided to decoder backpropagation 118 to propagate the loss function to individual nodes of the autoencoder, calculate each weight's contribution to the loss function, and adjust the weights accordingly using gradient descent. The gradients are provided to encoder backpropagation 120 to propagate the gradients back through the layers of the autoencoder, and update 122 the encoder weights and biases.

As discussed further herein, the ML model 110 can be in either the first computing device (e.g., a UE) or the second computing device (e.g., a gNB). The first or second computing devices can also include encoder 106, and the second computing device can include decoder 114.

In some embodiments, to reduce computational complexity on the decoder side, ML model 110 is used when decoder 114 decodes the CSI measurement data incorrectly (e.g., consistently decodes the CSI measurement data incorrectly). Incorrect decoding of channel quality can be observed by the first computing device (e.g., UE) and/or second computing device (e.g., gNB) indirectly, for example an unusually high packet rate, low throughput, handover of a UE to a target cell despite reporting of good channel quality, dropped calls, failure to establish a radio access bearer, etc. In some embodiments, such observations are triggers of the method.

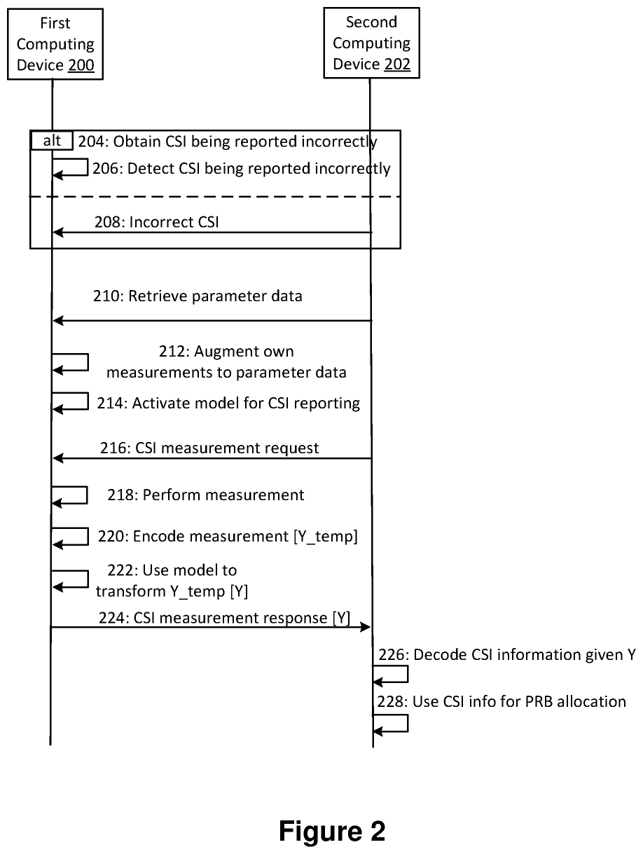

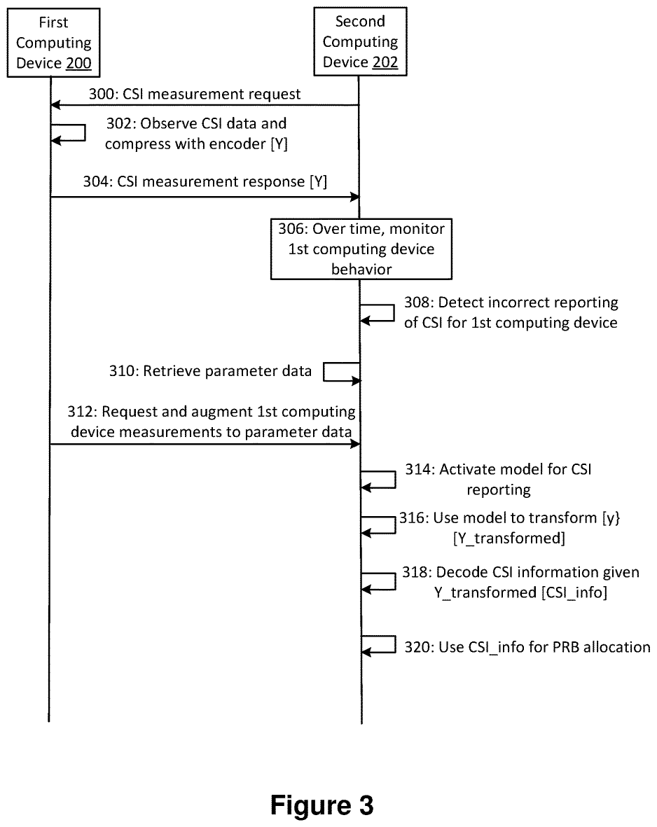

FIG. 2 is a signalling diagram illustrating operations performed by a first computing device 200 (e.g., a UE) for causal encoding of CSI. In the operations of FIG. 2, ML model 110 is part of the first computing device 200. FIG. 3 is a signalling diagram illustrating operations performed by a second computing device 202 (e.g., a gNB) for causal encoding and/or decoding of CSI. In the operations of FIG. 3, ML model 110 is part of the second computing device 202. In the example embodiments illustrated in FIGS. 2 and 3, first and second computing devices 200, 202 maintain one encoder and decoder, respectively, and ML model 110 transforms the latent space produced by the encoder to the expected input of the decoder. It is noted that when the first computing device 200 is a UE, and the UE changes a cell, the process resets.

Referring to FIG. 2, alternate embodiments are included for UE 200 obtaining 204 CSI being reported incorrectly. In one embodiment, UE 200 detects 206 incorrect reporting of CSI. In another embodiment, UE 200 receives 208 a reporting of incorrect CSI from gNB 202.

In operation 210, gNB 202 requests that UE 200 retrieve parameter data. UE 200, in operation 212, obtains a measurement of CSI data and augments the measurement to the parameter data. In operation 214, UE 200 activates ML model 110 for CSI reporting.

gNB 202, in operation 216, requests that UE 200 obtain a CSI measurement and report the CSI measurement to gNB 202. In operation 218, UE 200 obtains the measurement and, in operation 220, uses encoder 106 to compress the obtained measurement to a latent space representation, Yₜₑₘₚ. UE 200, in operation 222, uses ML model 110 to transform Yₜₑₘₚ to Y, and in operation 224, transmits a response including the CSI measurement Y to gNB 202. In operation, 226, gNB 202 decodes the CSI information given Y. In operation 228, gNB 202 uses the CSI information for a resource allocation (e.g., a physical resource block (PRB) allocation as illustrated in the example embodiment of FIG. 2).

Referring to FIG. 3, in operation 300, gNB 202 requests that UE 200 obtain a CSI measurement and report the CSI measurement to gNB 202. In operation 302, UE 200 obtains the CSI measurement and compresses the CSI measurement data with encoder 106 to a latent space representation, Yₜₑₘₚ. In operation 304, UE 200 transmits a response including the CSI measurement Y to gNB 202. In operation 306, over time, gNB 202 monitors behavior of UE 200. In operation 308, gNB 202 detects incorrect reporting of CSI for UE 200. gNB 202, in operation 310, retrieves parameter data. In operation 312, UE 200 transmits a request including to augment UE measurements of channel data to the general and specific parameters.

In operation 314, gNB 202 activates ML model 110 for CSI reporting. gNB 202, in operation 316 uses ML model 110 to transform Yₜₑₘₚ to Y, and in operation 318, decodes the CSI information given Y. In operation 320, gNB 202 uses the CSI information for a resource allocation (e.g., a physical resource block (PRB) allocation as illustrated in the example embodiment of FIG. 3).

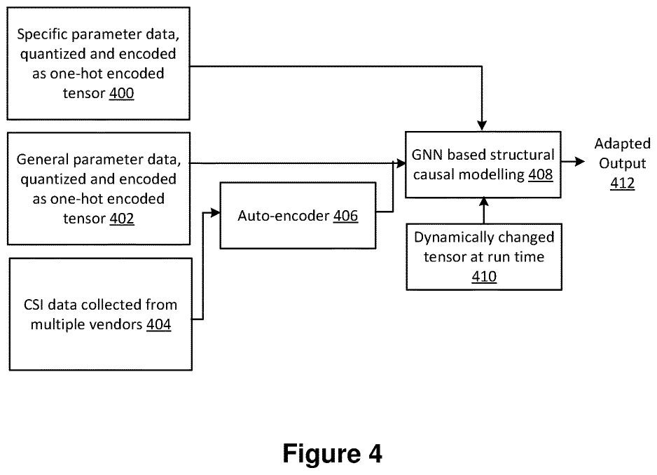

FIG. 4 is a block diagram illustrating a causally aware CSI encoding system in accordance with some embodiments of the present disclosure. As illustrated in the example embodiment of FIG. 4, specific parameter data 400 is quantized and encoded as a one-hot encoded tensor. General parameter data 402 is quantized and encoded as a one-hot encoded tensor. Observation data 404 including CSI data may be collected from multiple vendors. Specific parameter data 400 is input to a ML model illustrated as a graph neural network 408 based structural causal model. Specific parameter data 400 and general parameter data 402, as respective tenors, are input to GNN 408. CSI data 404 is auto encoded by encoder 406, and the output of encoder 406 is input to GNN 408. A dynamically changed tensor 410 at run time also is input to GNN 408. Responsive to the inputs, GNN 408 outputs an adapted output.

General parameter data of various embodiments of the present disclosure includes, without limitation:
1. Speed of a first computing device (e.g., UE), which also may be referred to as mobility. The speed can be determined by a network-based solution (e.g., a fifth generation (5G) positioning type of approach that uses triangulation and/or beamforming); and/or speed can be determined by the first computing device itself (e.g., using over the top technologies such as satellite positioning information (e.g., a global positioning system (GPS)). Latitude and longitude metrics can be used.
2. Line of Sight (LoS) or non-line-of-sight (NLOS) propagation, which can be a Boolean, for example, indicating whether a wave travels in a direct path or there are diffractions, refractions, and/or reflections due to obstacles.
3. Spatial channel correlation (e.g., a measure of independence between adjacent antennas in a MIMO antenna array). Spatial channel correlation can be, e.g., measured by an antenna correlation coefficient (ACC) that indicates interdependence. For example, the lower the ACC, the more independent the antennas are, generally leading to higher bandwidth. Far-field radiation pattern and S-parameter characterization are examples of processes that can be used to measure ACC.
4. Sub-carrier frequency, e.g., a frequency range of each of the subcarriers in a MIMO antenna.
5. Ambient environmental conditions that may affect signal propagation, such as precipitation, temperature, etc.
6. Instantaneous available bandwidth (IBW), e.g., a measure of a maximum amount of spectrum that can be processed by the network expressed, e.g., in KHz; and/or
7. A current state of the first computing device (e.g., IDLE or ACTIVE state)

The general parameters can be one-hot encoded where each of the general parameters is quantized to n-levels. In an example embodiment, n is 3; and is input as a n×8 bit tensor to the auto encoding module. The general parameters and specific parameters discussed below can be input as a tensor when building a causality graph.

Specific parameter data of various embodiments of the present disclosure includes, without limitation:
1. Perceived interference, such as a measure of signal to noise ratio or signal quality using as metrics, e.g., reference signal received power (RSRP), reference signal received quality (RSRQ), etc.
2. First computing device (e.g., UE) thresholds for a particular vendor, e.g., an acceptable level of loss in channel quality information (CQI) reconstruction at the network vendor.
3. Second computing device (e.g., gNB) thresholds for a particular vendor.
4. Power available at the first computing device (e.g., UE), expressed using at least one of a plurality of metrics, e.g., battery state of charge, rate of discharge, etc.
5. Nominal power parameter of the second computing device (e.g., gNB), such as a power amplifier (e.g., single or multiple transmission).
6. Radio equipment DC/DC input power; and/or
7. A first computing device (e.g., UE) defined power class, e.g., a defined industry power class for a maximum transmission power of a device, and maximum and minimum effective isotropic radiated power (EIRP) over new radio (NR).

As discussed above, the specific parameter data can be input as a tensor when building a causality graph.

Some embodiments include operations to build the ML model (e.g., a SCM), for example, using a Graph Neural Network (GNN). A GNN can be an additional encoding step at the encoder that is amenable for adaptation with changes in the exogenous variables, depending on parameter data (e.g., vendor or environmental changes). After building the GNN with observational data, the GNN can answer two types of queries:
(a) Interventional queries, such as, what would happen if one of the exogenous variables changes by a certain amount and/or
(b) Counterfactual queries, such as, what would have happened to a specific factual sample, given structural causal equations.

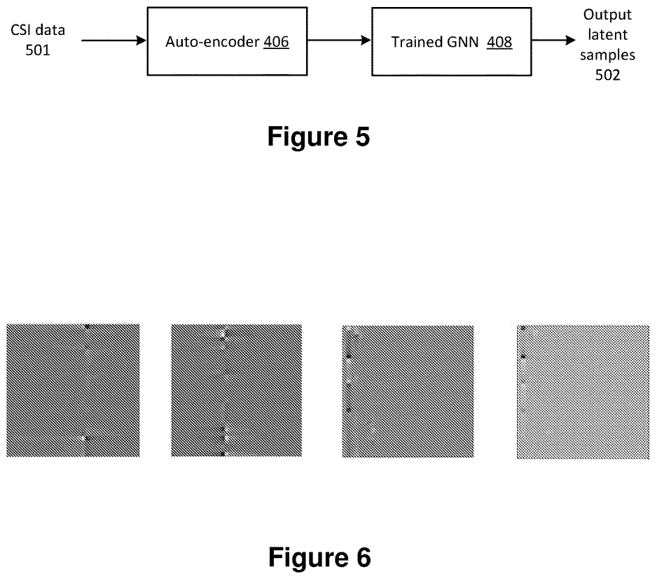

Mean squared error (MSE) metrics can be used to build the ML model (e.g., the GNN). FIG. 5 is a block diagram of an encoder that captures causal relationships in accordance with some embodiments of the present disclosure. As illustrated in FIG. 5, CSI data 501 is input to an autoencoder 406 trained with ADAM optimization and MSE. The output of autoencoder 406 is input to a trained GNN 408 that captures causal relationships. Trained GNN 408 outputs latent samples 502.

A ML model layer (e.g., a SCM layer) can be trained in a federated learning setting where data from multiple vendors or from different environmental conditions for the same vendor can incrementally improve the model. Online adaptation also may be included, which can be vendor specific for changes in environmental conditions, can be federated across vendors, etc.

In some embodiments that include a SCM, counterfactuals are generated that can aid the making the SCM explainable.

In an example embodiment of a simulation of the method, CSI data was used from Wen. The CSI data includes data collected from two settings: (1) Indoor data from a Pico cellular scenario at a 5.3 GHz band. A base station was positioned at the center of a 20 m square; and (2) Outdoor data from a rural setting at a 300 MHz band. A base station was positioned at the center of a 400 m square. For both scenarios, UEs were positioned randomly within the square. There were 32 antennas at the base station and 1024 subcarriers in use.

The CSI data was used to generate a synthetic parameter dataset, where matrixes can be transformed using scaling, changing orientation, changing position x, and position y. In a deployment scenario, it may be easier to collect the data by changing settings such as power and keeping a note of the distance and speed of the UE from the base station, and vendors of the UE(s) and gNB as available metadata. FIG. 6 shows sample CSI data from the indoor and outdoor settings.

In the example embodiment, causal factors were chosen that give rise to the CSI dataset, including indoor/outdoor setting labels, scale (similar to power in a real setting), orientation, and (x,y) positions. Orientation and (x,y) positions can be the position of the antenna array in real setting. The example embodiment included the following operations: (1) a variational autoencoder (VAE) was constructed from the underlying labels and images; (2) a SCM was built using the VAE and the underlying labels as inputs; and (3) interventional and counterfactual analysis was demonstrated when the labels were changed.

In an actual deployment, if vendor-to-vendor variations using the ML model (e.g., SCM) are captured, the method can include adapting the encoding to newer vendors. While in the simulation, a SCM was manually formed, in an actual deployment, the ML model can also be learnt using algorithms for causal discovery.

Causal causes that were included for the simulation were:
Shape: 3 values {indoor0, indoor1, outdoor0}—This selects three cases
Scale: 6 values linearly spaced in (0.5, 1)—The scale and orientation were 0 in the simulation
Orientation: 40 values in (0, 2 π)—The scale and orientation were 0 in the simulation
Position X: 32 values in (0, 1)
Position Y: 32 values in (0, 1)

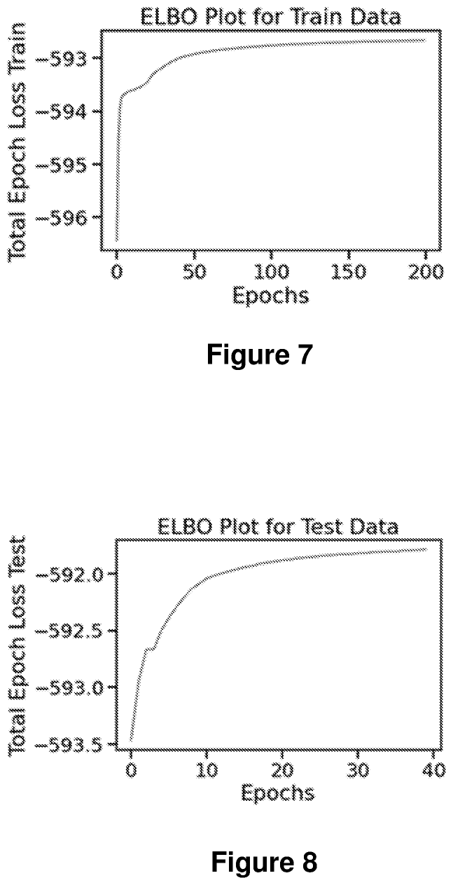

Training for the VAE was done on a graphics processing unit (GPU), with 200 epochs and an ADAM optimizer, and a learning rate of 1.0e-3. Test loss was calculated after every 5 training epochs. FIGS. 7 and 8 show train and test loss plots, respectively, for the simulation.

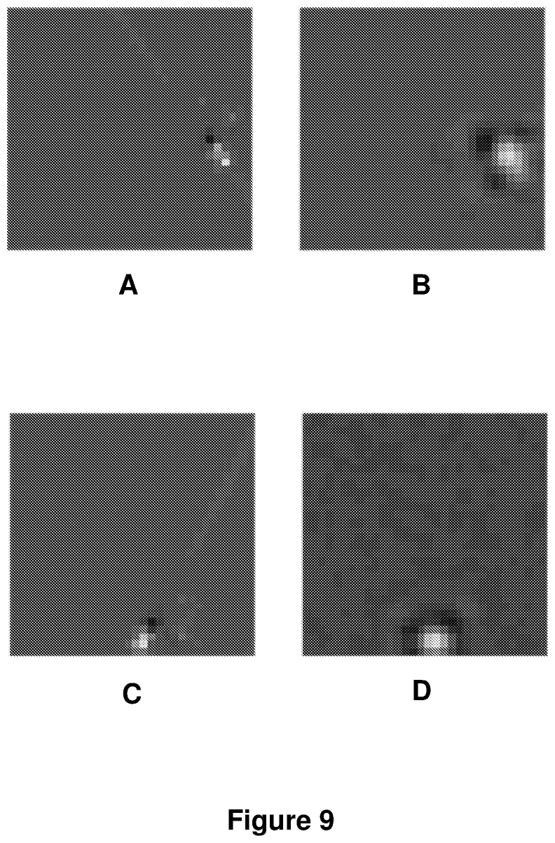

FIGS. 9A-D are images of sample reconstructions from the VAE. Accuracy can be increased by increasing the number of training epochs.

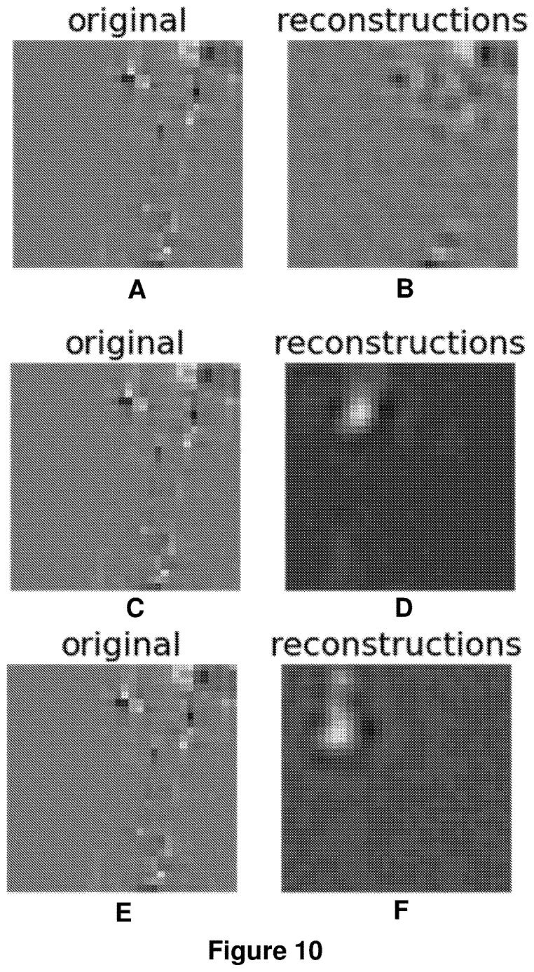

FIGS. 10 A-F are images of results of the VAE reconstruction where causal parameters were changed. FIG. 10A is an original image with no change: tensor([[0., 2., 4., 38., 7., 5.]], device=‘cuda:0’), and FIG. 10B is a sample VAE reconstruction of the image of FIG. 10A. FIG. 10C is an original image with change in shape: tensor([[0., 1., 4., 38., 7., 5.]], device=‘cuda:0’), and FIG. 10D is a sample VAE reconstruction of the image of FIG. 10C. FIG. 10E is an original image with change in orientation: tensor([[0., 1., 4., 1., 7., 5.]], device=‘cuda:0’), and FIG. 10F is a sample VAE reconstruction of the image of FIG. 10E.

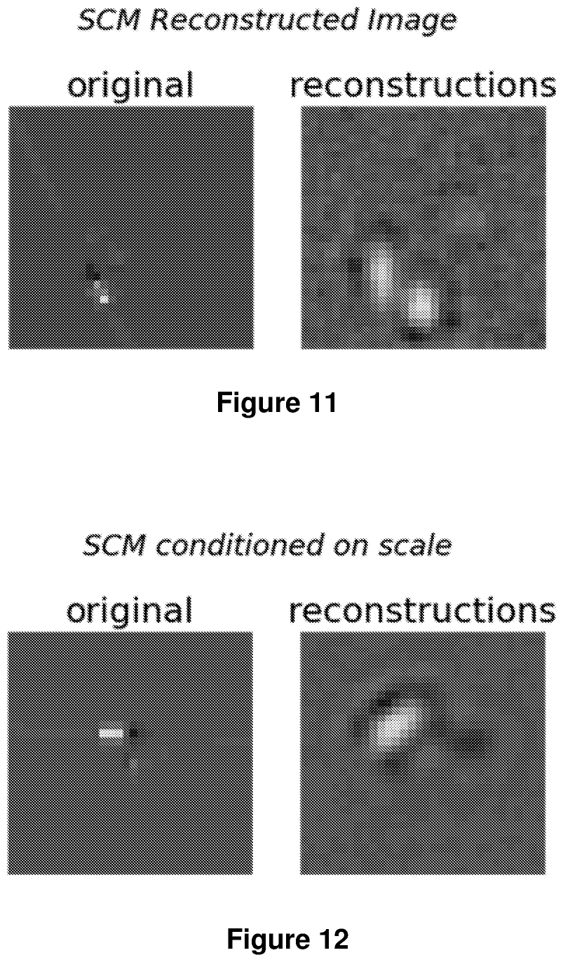

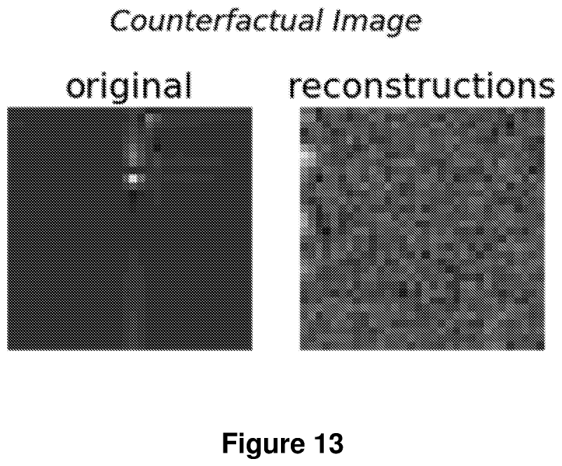

In the example embodiment, next, the SCM was constructed, and observational, interventional, and counterfactual examples are shown in FIGS. 11, 12, and 13, respectively. FIG. 11 includes an original CSI image and a CSI image reconstructed with the SCM. FIG. 12 includes an original CSI image and a CSI image reconstructed with intervention on scale. FIG. 13 includes an original CSI image and a CSI counterfactual image reconstructed.

Thus, certain embodiments may provide one or more of the following technical advantages. Use of causal autoencoding may result in adaption to different vendors based on interventional queries. As illustrated in the example embodiment of the simulation, the method can adapt to Gaussian noise, with sufficient training, and can work for random noise with other distributions as well. Energy and power savings may be achieved as different ML models do not need to be stored for each vendor. With adaptions, one ML model can adapt based on operation conditions and vendor settings. Additionally, the ML model may be explainable via counterfactuals. Moreover, using federated learning, the method may adapt to new vendors and/or different environmental settings.

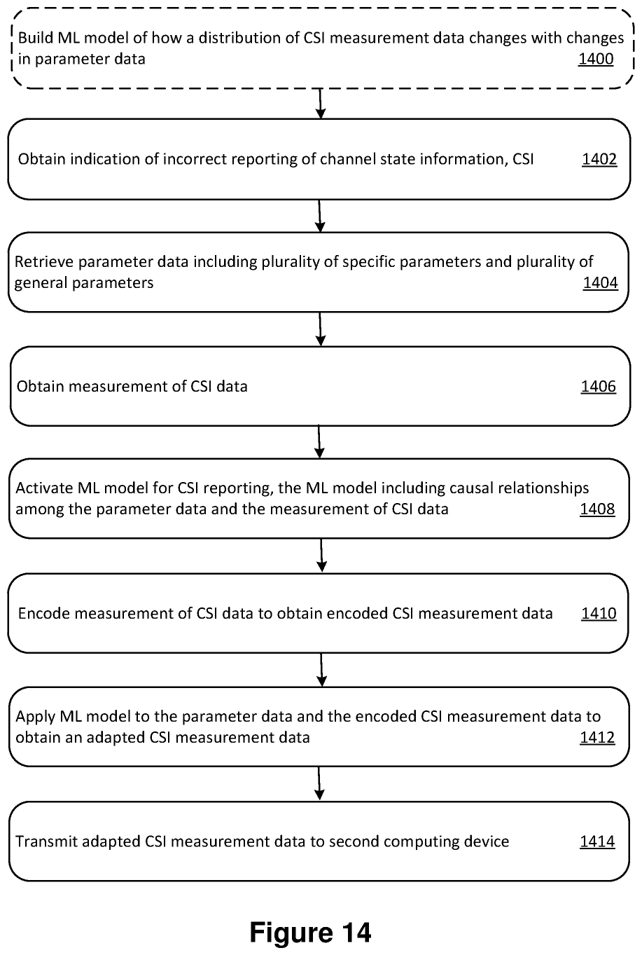

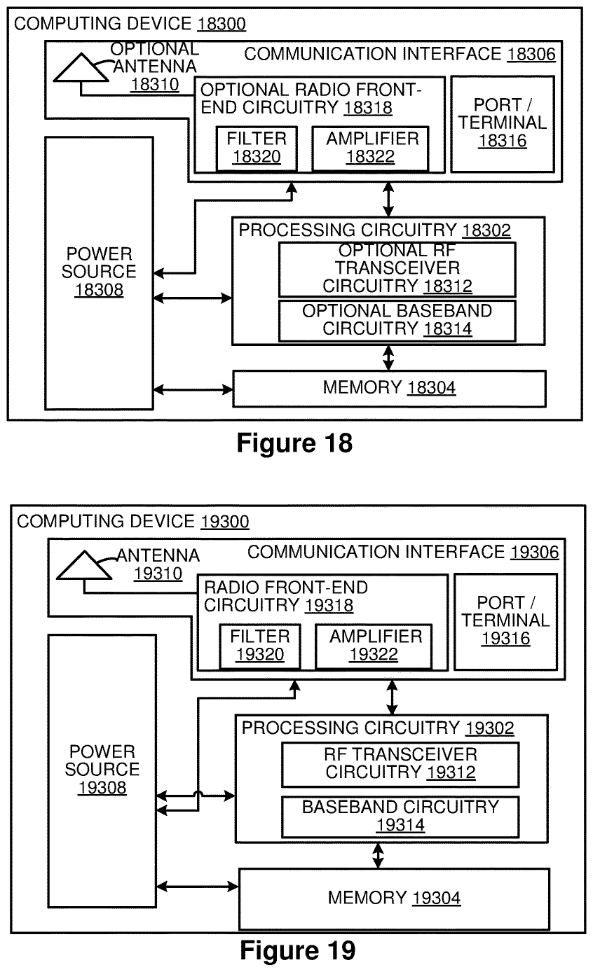

FIG. 14 is a flowchart of operations of a first computing device 200, 18300 (implemented using the structure of the block diagram of FIG. 18) in accordance with some embodiments of the present disclosure. For example, modules may be stored in memory 18304 of FIG. 18, and these modules may provide instructions so that when the instructions of a module are executed by respective first computing device processing circuitry 18302, processing circuitry 18302 performs respective operations of the flow charts.

Referring to FIG. 14, a computer-implemented method performed by the first computing device for causal encoding of CSI is provided. The method includes obtaining (1402) an indication of incorrect reporting of CSI; retrieving (1404) parameter data including a plurality of specific parameters and a plurality of general parameters; obtaining (1406) a measurement of CSI data; and activating a ML model for CSI reporting. The ML model includes causal relationships among the parameter data and the measurement of CSI data. The method further includes encoding (1410) the measurement of CSI data to obtain encoded CSI measurement data; applying (1412) the ML model to the parameter data and the encoded CSI measurement data to obtain an adapted CSI measurement data; and transmitting (1414) the adapted CSI measurement data to a second computing device.

The ML model can include a SCM.

In some embodiments, the ML model models the CSI measurement data as a function of the plurality of specific parameters and the plurality of general parameters.

The ML model can include a directed acyclic graph comprising a plurality of nodes that correspond to the CSI measurement data and a plurality of directed edges that account for a causal parent-child relationship.

The obtaining (1402) can include at least one of (i) detecting the incorrect reporting of CSI, and (ii) receiving a message from the second computing device comprising the incorrect reporting of CSI.

The plurality of general parameters can include a plurality of at least one or more of (i) a speed of the first computing device, (ii) a location of the first computing device, (iii) a direction of movement of the first computing device, (iv) a line-of-sight or a non-line-of-sight propagation of a signal between the first computing device and the second computing device, (v) a spatial channel correlation, (vi) one or more sub-carrier frequencies, (vii) an environmental condition, (viii) an available bandwidth, and (ix) a current state of the first computing device.

The plurality of specific parameters can include a plurality of at least one or more of (i) a measurement of perceived interference, (ii) a threshold for the first computing device for a particular vendor, (iii) a threshold for the second computing device for a particular vendor, (iv) a power available at the first computing device, (v) a nominal power parameter of the second computing device, (vi) an input power to the second computing device, and (vii) a specified power class for the first computing device.

In some embodiments, the method further includes building (1400) the ML model using a GNN, the plurality of specific parameters, the plurality of general parameters, and CSI data. The built ML model can model how a distribution of the CSI measurement data changes with changes in the specific and general parameters.

The building (1400) can include encoding the plurality of specific parameters and the plurality of general parameters, respectively; inputting to the GNN (i) the encoded plurality of specific parameters as a tensor, (ii) the encoded plurality of general parameters as a tensor, and (iii) the CSI data; and training the GNN with an adaptive algorithm and an error metric. The trained GNN can capture causal relationships between the plurality of specific parameters, the plurality of general parameters, and the CSI data.

In some embodiments, the ML model is trained in a federated learning setting.

In some embodiments, the first computing device is a UE, and the second computing device is a network node.

Various operations from the flow chart of FIG. 14 may be optional with respect to some embodiments of first computing devices and related methods. For example, operations of block 1400 may be optional.

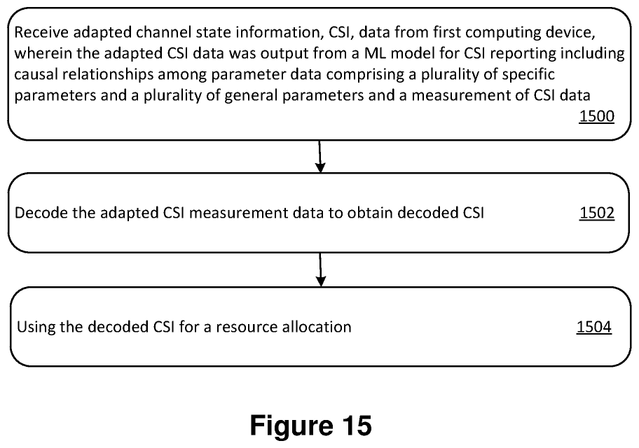

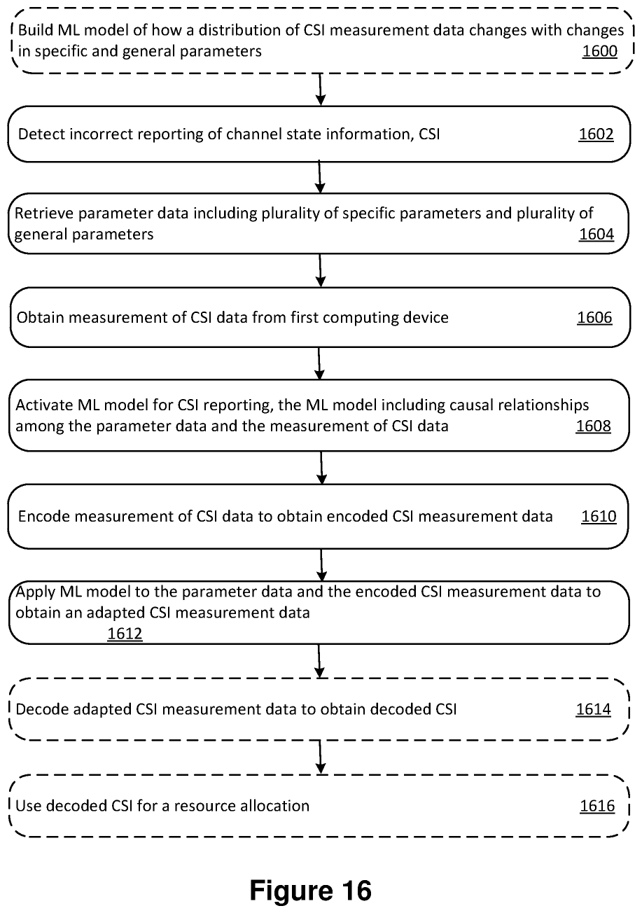

FIGS. 15 and 16 are flowcharts of operations of a second computing device 202, 19300 (implemented using the structure of the block diagram of FIG. 19) in accordance with some embodiments of the present disclosure. For example, modules may be stored in memory 19304 of FIG. 19, and these modules may provide instructions so that when the instructions of a module are executed by respective second computing device processing circuitry 19302, processing circuitry 19302 performs respective operations of the flow chart.

Referring to FIG. 15, a computer-implemented method performed by the second computing device for decoding causally encoded CSI is provided. The method includes receiving (1500) an adapted CSI data from a first computing device, where the adapted CSI data was output from a ML, model for CSI reporting including causal relationships among parameter data comprising a plurality of specific parameters and a plurality of general parameters and a measurement of CSI data. The method further includes decoding (1502) the adapted CSI measurement data to obtain decoded CSI; and using (1504) the decoded CSI for a resource allocation.

Referring to FIG. 16, a computer-implemented method performed by the second computing device for causal encoding and decoding of CSI is provided. The method includes detecting (1602) an incorrect reporting of CSI for a first computing device; retrieving (1604) parameter data comprising a plurality of specific parameters and a plurality of general parameters; and obtaining (1606) a measurement of CSI data from the first computing device. The method further includes activating (1608) a ML model for CSI reporting. The ML model includes causal relationships among the parameter data and the measured CSI data. The method further includes encoding (1610) the measurement CSI data to obtain encoded CSI measurement data; and applying (1612) the ML model to the parameter data and the encoded CSI measurement data to obtain an adapted CSI measurement data.

In some embodiments, the method further includes decoding (1614) adapted CSI measurement data to obtain decoded CSI; and using (1616) the decoded CSI for a resource allocation.

The ML model can include a SCM.

In some embodiments, the ML model models the CSI measurement data as a function of the plurality of specific parameters and the plurality of general parameters.

The ML model can include a directed acyclic graph comprising a plurality of nodes that correspond to the CSI measurement data and a plurality of directed edges that account for a causal parent-child relationship between the CSI measurement data and the parameter data.

The plurality of general parameters can include a plurality of at least one or more of (i) a speed of the first computing device, (ii) a location of the first computing device, (iii) a direction of movement of the first computing device, (iv) a line-of-sight or a non-line-of-sight propagation of a signal between the first computing device and the second computing device, (v) a spatial channel correlation, (vi) one or more sub-carrier frequencies, (vii) an environmental condition, (viii) an available bandwidth, and (ix) a current state of the first computing device.

The plurality of specific parameters can include a plurality of at least one or more of (i) a measurement of perceived interference, (ii) a threshold for the first computing device for a particular vendor, (iii) a threshold for the second computing device for a particular vendor, (iv) a power available at the first computing device, (v) a nominal power parameter of the second computing device, (vi) an input power to the second computing device, and (vii) a specified power class for the first computing device.

In some embodiments, the method further includes building (1600) the ML model using a GNN, the plurality of specific parameters, the plurality of general parameters, and CSI data. The built ML model can model how a distribution of the CSI measurement data changes with changes in the specific and general parameters.

The building (1600) can include encoding the plurality of specific parameters and the plurality of general parameters, respectively; inputting to the GNN (i) the encoded plurality of specific parameters as a tensor, (ii) the encoded plurality of general parameters as a tensor, and (iii) the CSI data; and training the GNN with an adaptive algorithm and an error metric. The trained GNN can capture causal relationships between the plurality of specific parameters, the plurality of general parameters, and the CSI data.

In some embodiments, the ML model is trained in a federated learning setting.

In some embodiments, the first computing device is a UE, and the second computing device is a network node.

Various operations from the flow chart of FIG. 16 may be optional with respect to some embodiments of second computing devices and related methods. For example, operations of blocks 1600, 1614, and 1616 of FIG. 16 may be optional.

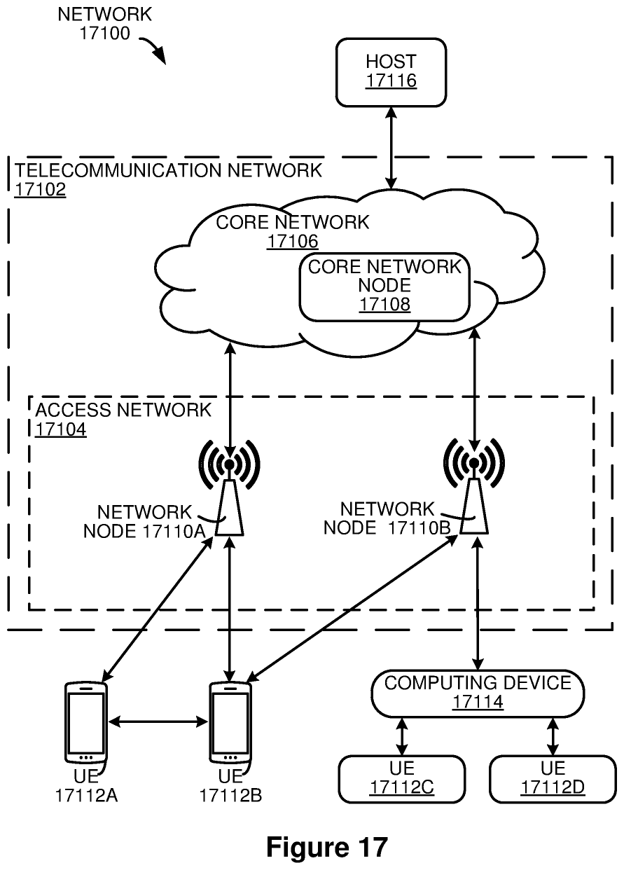

Example embodiments of the methods of the present disclosure may be implemented in a network that includes, without limitation a telecommunication network, as illustrated on FIG. 17. The telecommunications network 17102 may include an access network 17104, such as a RAN, and a core network 17106, which includes one or more core network nodes 17108. The access network 17104 may include one or more access nodes 17110A. 17110B, such as network nodes (e.g., base stations), or any other similar Third Generation Partnership project (3GPP) access node or non-3GPP access point. The network nodes 17110 facilitate direct or indirect connection of first computing devices 1711A-D (e.g., a UE), such as by and/or other first computing devices to the core network 17106 over one or more wireless connections.

Example wireless communications over a wireless connection include transmitting and/or receiving wireless signals using electromagnetic waves, radio waves, infrared waves, and/or other types of signals suitable for conveying information without the use of wires, cables, or other material conductors. Moreover, in different embodiments, the network may include any number of wired or wireless networks, network nodes, UEs, computing devices, and/or any other components or systems that may facilitate or participate in the communication of data and/or signals whether via wired or wireless connections. The network may include and/or interface with any type of communication, telecommunication, data, cellular, radio network, and/or other similar type of system.

As a whole, the network 17100 enables connectivity between the first computing devices 17112 and second computing device(s) 17110. In that sense, the network 17100 may be configured to operate according to predefined rules or procedures, such as specific standards that include, but are not limited to: Global System for Mobile Communications (GSM); Universal Mobile Telecommunications System (UMTS); Long Term Evolution (LTE), and/or other suitable 2G, 3G, 4G, 5G standards, or any applicable future generation standard (e.g., 6G); wireless local area network (WLAN) standards, such as the Institute of Electrical and Electronics Engineers (IEEE) 802.11 standards (WiFi); and/or any other appropriate wireless communication standard, such as the Worldwide Interoperability for Microwave Access (WiMax), Bluetooth, Z-Wave, Near Field Communication (NFC) ZigBee, LiFi, and/or any low-power wide-area network (LPWAN) standards such as LoRa and Sigfox.

In some examples, the telecommunication network 17102 is a cellular network that implements 3GPP standardized features. Accordingly, the telecommunications network 17102 may support network slicing to provide different logical networks to different devices that are connected to the telecommunication network. For example, the telecommunications network 17102 may provide Ultra Reliable Low Latency Communication (URLLC) services to some first computing devices (e.g., UEs), while providing Enhanced Mobile Broadband (eMBB) services to other first computing devices, and/or Massive Machine Type Communication (mMTC)/Massive IoT services to yet further first computing devices.

In some examples, the network 17100 is not limited to including a RAN, and rather includes any that includes any programmable/configurable decentralized access point or network element that also records data from performance measurement points in the network 17100.

In some examples, first computing devices and/or second computing devices are configured as a computer without radio/baseband, etc. attached.

The method of the present disclosure is light-weight and, thus, amenable to distributed node and cloud implementation. Various distributed processing options may be used that suit data source, storage, compute, and coordination. For example, data sampling may be done at a node (e.g., worker node), with data analysis, inference, ML model creation, ML model sharing, and CSI encoding performed at a cloud server (e.g., master).

In some embodiments, core network virtual network functions (VNFs) are included, without limitation, a network data analytics function and an operations support system (OSS).

In some embodiments, implementation includes implementation in an open RAN (ORAN).

Methods of the present disclosure may be performed by a first computing device (e.g., any first computing devices 17112A-D of FIG. 17 (one or more of which may be generally referred to as first computing device 17112), or computing device 18300 of FIG. 18).

Referring to FIG. 18, as previously discussed, a first computing device can include first computing device 20o of FIG. 2 or computing device 18300 of FIG. 18. First computing device includes equipment capable, configured, arranged, and/or operable for causal encoding of CSI. As previously discussed, examples of first computing devices include, but are not limited to, a computer, a decentralized edge device, a decentralized edge server, and a UE. In some embodiments, the first computing device 18300 includes processing circuitry 18302 that is operatively coupled to a memory 18304, a ML model and an autoencoder (not illustrated), and/or any other component, or any combination thereof. Certain first computing devices may utilize all or a subset of the components shown in FIG. 18. The level of integration between the components may vary from one first computing device to another first computing device. Further, certain first computing devices may contain multiple instances of a component, such as multiple processors, memories, transceivers, transmitters, receivers, etc.

The processing circuitry 18302 is configured to process instructions and data and may be configured to implement any sequential state machine operative to execute instructions stored as machine-readable computer programs in the memory 18304 and/or the ML model. The processing circuitry 18302 may be implemented as one or more hardware-implemented state machines (e.g., in discrete logic, field-programmable gate arrays (FPGAs), application specific integrated circuits (ASICs), etc.); programmable logic together with appropriate firmware; one or more stored computer programs, general-purpose processors, such as a microprocessor or digital signal processor (DSP), together with appropriate software; or any combination of the above. For example, the processing circuitry 18302 may include multiple central processing units (CPUs).

The memory 18304 and/or the ML model may be or be configured to include memory such as random access memory (RAM), read-only memory (ROM), programmable read-only memory (PROM), erasable programmable read-only memory (EPROM), electrically erasable programmable read-only memory (EEPROM), magnetic disks, optical disks, hard disks, removable cartridges, flash drives, and so forth. In one example, the memory 18304 and/or the ML model includes one or more application programs, such as an operating system, web browser application, a widget, gadget engine, or other application, and corresponding data. The memory 18304 and/or the ML model may store, for use by the first computing device 18300, any of a variety of various operating systems or combinations of operating systems.

The memory 18304 and/or the ML model may be configured to include a number of physical drive units, such as redundant array of independent disks (RAID), flash memory, USB flash drive, external hard disk drive, thumb drive, pen drive, key drive, high-density digital versatile disc (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as tamper resistant module in the form of a universal integrated circuit card (UICC) including one or more subscriber identity modules (SIMs), such as a USIM and/or ISIM, other memory, or any combination thereof. The UICC may for example be an embedded UICC (eUICC), integrated UICC (iUICC) or a removable UICC commonly known as ‘SIM card.’ The memory 18304 and/or the ML model may allow the first computing device 18300 to access instructions, application programs and the like, stored on transitory or non-transitory memory media, to off-load data, or to upload data. An article of manufacture, such as one utilizing a network may be tangibly embodied as or in the memory 18304 and/or ML model, which may be or comprise a device-readable storage medium.

The processing circuitry 18302 may be configured to communicate with an access network or other network using a communication interface 18306. The communication interface may comprise one or more communication subsystems and may include or be communicatively coupled to an optional antenna. The communication interface 18306 may include one or more transceivers used to communicate, such as by communicating with one or more remote transceivers of another device capable of wireless communication (e.g., another first computing device or a second computing device such as a network node). Each transceiver may include a transmitter and/or a receiver appropriate to provide network communications (e.g., optical, electrical, frequency allocations, and so forth). Moreover, the optional transmitter and receiver may be coupled to one or more optional antennas and may share circuit components, software or firmware, or alternatively be implemented separately.

In the illustrated embodiment, communication functions of the communication interface 18306 may include cellular communication, Wi-Fi communication, LPWAN communication, data communication, voice communication, multimedia communication, short-range communications such as Bluetooth, near-field communication, location-based communication such as the use of the global positioning system (GPS) to determine a location, another like communication function, or any combination thereof. Communications may be implemented in according to one or more communication protocols and/or standards, such as IEEE 802.11, Code Division Multiplexing Access (CDMA), Wideband Code Division Multiple Access (WCDMA), GSM, LTE, New Radio (NR), UMTS, WiMax, Ethernet, transmission control protocol/internet protocol (TCP/IP), synchronous optical networking (SONET), Asynchronous Transfer Mode (ATM), QUIC, Hypertext Transfer Protocol (HTTP), and so forth.

Further methods of the present disclosure may be performed by a second computing device (e.g., second computing device 19300 of FIG. 19 or second computing device 202 of FIG. 2). As previously discussed, second computing device includes equipment capable, configured, arranged, and/or operable for causal encoding of CSI and/or decoding of CSI. Examples of second computing devices include, but are not limited to, a computer, a decentralized edge device, a decentralized edge server, a cloud node, a cloud server, and centralized or distributed BS in a RAN (e.g., gNBs, eNBs, core network nodes, APs (e.g., radio access points) etc.). In some embodiments, the second computing device 19300 includes modules may be stored in memory 19304, a ML model, autoencoder, and/or decoder (not illustrated), and these modules may provide instructions so that when the instructions of a module are executed by processing circuitry 19302 of FIG. 19, the second computing device performs respective operations of methods in accordance with various embodiments of the present disclosure.

Certain second computing devices may utilize all or a subset of the components shown in FIG. 19. The level of integration between the components may vary from one second computing device to another second computing device. Further, certain second computing devices may contain multiple instances of a component, such as multiple processors, memories, transceivers, transmitters, receivers, etc.

The processing circuitry 19302 is configured to process instructions and data and may be configured to implement any sequential state machine operative to execute instructions stored as machine-readable computer programs in the memory 19304, the ML model, autoencoder, and/or the decoder. The processing circuitry 19302 may be implemented as one or more hardware-implemented state machines (e.g., in discrete logic, field-programmable gate arrays (FPGAs), application specific integrated circuits (ASICs), etc.); programmable logic together with appropriate firmware; one or more stored computer programs, general-purpose processors, such as a microprocessor or digital signal processor (DSP), together with appropriate software; or any combination of the above. For example, the processing circuitry 19302 may include multiple central processing units (CPUs).

The memory 19304, the ML model, autoencoder, and/or the decoder may be or be configured to include memory such as random access memory (RAM), read-only memory (ROM), programmable read-only memory (PROM), erasable programmable read-only memory (EPROM), electrically erasable programmable read-only memory (EEPROM), magnetic disks, optical disks, hard disks, removable cartridges, flash drives, and so forth. In one example, the memory 19304, the ML model, autoencoder, and/or the decoder includes one or more application programs, such as an operating system, web browser application, a widget, gadget engine, or other application, and corresponding data. The memory 19304, the ML model, autoencoder, and/or the decoder may store, for use by the second computing device 19300, any of a variety of various operating systems or combinations of operating systems.

The memory 19304, the ML model, autoencoder, and/or the decoder may be configured to include a number of physical drive units, such as redundant array of independent disks (RAID), flash memory, USB flash drive, external hard disk drive, thumb drive, pen drive, key drive, high-density digital versatile disc (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as tamper resistant module in the form of a universal integrated circuit card (UICC) including one or more subscriber identity modules (SIMs), such as a USIM and/or ISIM, other memory, or any combination thereof. The UICC may for example be an embedded UICC (eUICC), integrated UICC (iUICC) or a removable UICC commonly known as ‘SIM card.’ The memory 19304, the ML model, autoencoder, and/or the decoder may allow the second computing device 19300 to access instructions, application programs and the like, stored on transitory or non-transitory memory media, to off-load data, or to upload data. An article of manufacture, such as one utilizing a network may be tangibly embodied as or in the memory 19304, the ML model, autoencoder, and/or the decoder, which may be or comprise a device-readable storage medium.

The processing circuitry 19302 may be configured to communicate with an access network or other network using a communication interface 19306. The communication interface 19306 may comprise one or more communication subsystems and may include or be communicatively coupled to an optional antenna. The communication interface 19306 may include one or more transceivers used to communicate, such as by communicating with one or more remote transceivers of another device capable of wireless communication (e.g., a first computing device or another second computing device). Each transceiver may include a transmitter and/or a receiver appropriate to provide network communications (e.g., optical, electrical, frequency allocations, and so forth). Moreover, the optional transmitter and receiver may be coupled to one or more optional antennas and may share circuit components, software or firmware, or alternatively be implemented separately.

In the illustrated embodiment, communication functions of the communication interface 19306 may include cellular communication, Wi-Fi communication, LPWAN communication, data communication, voice communication, multimedia communication, short-range communications such as Bluetooth, near-field communication, location-based communication such as the use of the GPS to determine a location, another like communication function, or any combination thereof. Communications may be implemented in according to one or more communication protocols and/or standards, such as IEEE 802.11, CDMA, WCDMA, GSM, LTE, NR, UMTS, WiMax, Ethernet, TCP/IP, SONET, ATM, QUIC, HTTP, and so forth.

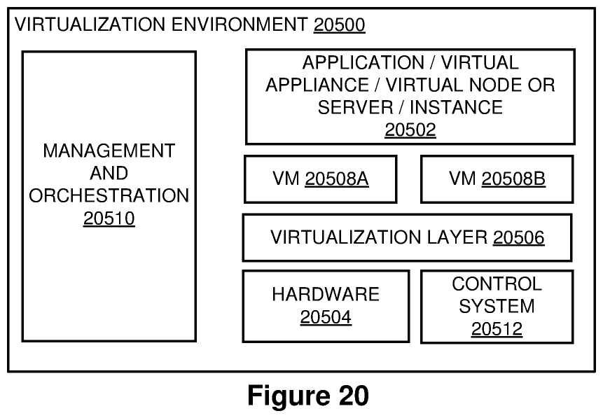

FIG. 20 is a block diagram illustrating a virtualization environment 20500 in which functions implemented by some embodiments may be virtualized. In the present context, virtualizing means creating virtual versions of apparatuses or devices which may include virtualizing hardware platforms, storage devices and networking resources. As used herein, virtualization can be applied to any device described herein, or components thereof, and relates to an implementation in which at least a portion of the functionality is implemented as one or more virtual components. Some or all of the functions described herein may be implemented as virtual components executed by one or more virtual machines (VMs) implemented in one or more virtual environments 20500 hosted by one or more of hardware nodes, such as a hardware computing device that operates as a second computing device (e.g., a network node), a first computing device (e.g., a UE), core network node, or host. Further, in embodiments in which the virtual node does not require radio connectivity (e.g., a core network node or host), then the node may be entirely virtualized.

Applications 20502 (which may alternatively be called software instances, virtual appliances, network functions, virtual nodes, virtual network functions, etc.) are run in the virtualization environment Q400 to implement some of the features, functions, and/or benefits of some of the embodiments disclosed herein.

Hardware 20504 includes processing circuitry, memory that stores software and/or instructions executable by hardware processing circuitry, and/or other hardware devices as described herein, such as a network interface, input/output interface, and so forth. Software may be executed by the processing circuitry to instantiate one or more virtualization layers 20506 (also referred to as hypervisors or virtual machine monitors (VMMs)), provide VMs 20508a and 20508b (one or more of which may be generally referred to as VMs 20508), and/or perform any of the functions, features and/or benefits described in relation with some embodiments described herein. The virtualization layer 20506 may present a virtual operating platform that appears like networking hardware to the VMs 20508.

The VMs 20508 comprise virtual processing, virtual memory, virtual networking or interface and virtual storage, and may be run by a corresponding virtualization layer 20506. Different embodiments of the instance of a virtual appliance 20502 may be implemented on one or more of VMs 20508, and the implementations may be made in different ways. Virtualization of the hardware is in some contexts referred to as network function virtualization (NFV or VNF). NFV may be used to consolidate many network equipment types onto industry standard high volume server hardware, physical switches, and physical storage, which can be located in data centers, and customer premise equipment.

In the context of NFV, a VM 20508 may be a software implementation of a physical machine that runs programs as if they were executing on a physical, non-virtualized machine. Each of the VMs 20508, and that part of hardware 20504 that executes that VM, be it hardware dedicated to that VM and/or hardware shared by that VM with others of the VMs, forms separate virtual network elements. Still in the context of NFV, a virtual network function is responsible for handling specific network functions that run in one or more VMs 20508 on top of the hardware 20504 and corresponds to the application 20502.

Hardware 20504 may be implemented in a standalone network node with generic or specific components. Hardware 20504 may implement some functions via virtualization. Alternatively, hardware 20504 may be part of a larger cluster of hardware (e.g. such as in a data center or CPE) where many hardware nodes work together and are managed via management and orchestration 20510, which, among others, oversees lifecycle management of applications 20502. In some embodiments, hardware 20504 is coupled to one or more radio units that each include one or more transmitters and one or more receivers that may be coupled to one or more antennas. Radio units may communicate directly with other hardware nodes via one or more appropriate network interfaces and may be used in combination with the virtual components to provide a virtual node with radio capabilities, such as a radio access node or a base station. In some embodiments, some signaling can be provided with the use of a control system 20512 which may alternatively be used for communication between hardware nodes and radio units

Although the first and second computing devices described herein may include the illustrated combination of hardware components, other embodiments may comprise first and/or second computing devices with different combinations of components. It is to be understood that these first and/or second computing devices may comprise any suitable combination of hardware and/or software needed to perform the tasks, features, functions and methods disclosed herein. Determining, calculating, obtaining or similar operations described herein may be performed by processing circuitry, which may process information by, for example, converting the obtained information into other information, comparing the obtained information or converted information to information stored in the first and/or second computing device, and/or performing one or more operations based on the obtained information or converted information, and as a result of said processing making a determination. Moreover, while components are depicted as single boxes located within a larger box, or nested within multiple boxes, in practice, first and/or second computing devices may comprise multiple different physical components that make up a single illustrated component, and functionality may be partitioned between separate components. For example, a communication interface may be configured to include any of the components described herein, and/or the functionality of the components may be partitioned between the processing circuitry and the communication interface. In another example, non-computationally intensive functions of any of such components may be implemented in software or firmware and computationally intensive functions may be implemented in hardware.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the first and/or second computing device, but are enjoyed by the first and/or second computing device as a whole, and/or by end users and a wireless network generally.

In the above description of various embodiments of the present disclosure, it is to be understood that the terminology used herein is for the purpose of describing particular embodiments only and is not intended to be limiting of present inventive concepts. Unless otherwise defined, all terms (including technical and scientific terms) used herein have the same meaning as commonly understood by one of ordinary skill in the art to which present inventive concepts belong. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

When an element is referred to as being “connected”, “coupled”, “responsive”, or variants thereof to another element, it can be directly connected, coupled, or responsive to the other element or intervening elements may be present. In contrast, when an element is referred to as being “directly connected”, “directly coupled”, “directly responsive”, or variants thereof to another element, there are no intervening elements present. Like numbers refer to like elements throughout. Furthermore, “coupled”, “connected”, “responsive”, or variants thereof as used herein may include wirelessly coupled, connected, or responsive. As used herein, the singular forms “a”, “an” and “the” are intended to include the plural forms as well, unless the context clearly indicates otherwise. Well-known functions or constructions may not be described in detail for brevity and/or clarity. The term “and/or” includes any and all combinations of one or more of the associated listed items.

It will be understood that although the terms first, second, third, etc. may be used herein to describe various elements/operations, these elements/operations should not be limited by these terms. These terms are only used to distinguish one element/operation from another element/operation. Thus, a first element/operation in some embodiments could be termed a second element/operation in other embodiments without departing from the teachings of present inventive concepts. The same reference numerals or the same reference designators denote the same or similar elements throughout the specification.

As used herein, the terms “comprise”, “comprising”, “comprises”, “include”, “including”, “includes”, “have”, “has”, “having”, or variants thereof are open-ended, and include one or more stated features, integers, elements, steps, components or functions but does not preclude the presence or addition of one or more other features, integers, elements, steps, components, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

Example embodiments are described herein with reference to block diagrams and/or flowchart illustrations of computer-implemented methods, apparatus (systems and/or devices) and/or computer program products. It is understood that a block of the block diagrams and/or flowchart illustrations, and combinations of blocks in the block diagrams and/or flowchart illustrations, can be implemented by computer program instructions that are performed by one or more computer circuits. These computer program instructions may be provided to a processor circuit of a general purpose computer circuit, special purpose computer circuit, and/or other programmable data processing circuit to produce a machine, such that the instructions, which execute via the processor of the computer and/or other programmable data processing apparatus, transform and control transistors, values stored in memory locations, and other hardware components within such circuitry to implement the functions/acts specified in the block diagrams and/or flowchart block or blocks, and thereby create means (functionality) and/or structure for implementing the functions/acts specified in the block diagrams and/or flowchart block(s).

These computer program instructions may also be stored in a tangible computer-readable medium that can direct a computer or other programmable data processing apparatus to function in a particular manner, such that the instructions stored in the computer-readable medium produce an article of manufacture including instructions which implement the functions/acts specified in the block diagrams and/or flowchart block or blocks. Accordingly, embodiments of present inventive concepts may be embodied in hardware and/or in software (including firmware, resident software, micro-code, etc.) that runs on a processor such as a digital signal processor, which may collectively be referred to as “circuitry,” “a module” or variants thereof.

It should also be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of inventive concepts. Moreover, although some of the diagrams include arrows on communication paths to show a primary direction of communication, it is to be understood that communication may occur in the opposite direction to the depicted arrows.

Many variations and modifications can be made to the embodiments without substantially departing from the principles of the present inventive concepts. All such variations and modifications are intended to be included herein within the scope of present inventive concepts. Accordingly, the above disclosed subject matter is to be considered illustrative, and not restrictive, and the examples of embodiments are intended to cover all such modifications, enhancements, and other embodiments, which fall within the spirit and scope of present inventive concepts. Thus, to the maximum extent allowed by law, the scope of present inventive concepts is to be determined by the broadest permissible interpretation of the present disclosure including the examples of embodiments and their equivalents, and shall not be restricted or limited by the foregoing detailed description.

1. A computer-implemented method performed by a first computing device for causal encoding of channel state information, the method comprising:
obtaining an indication of incorrect reporting of channel state information, CSI;
retrieving parameter data comprising a plurality of specific parameters and a plurality of general parameters;
obtaining a measurement of CSI data;
activating a machine learning, ML, model for CSI reporting, the ML model comprising causal relationships among the parameter data and the measurement of CSI data;
encoding the measurement of CSI data to obtain encoded CSI measurement data;
applying the ML model to the parameter data and the encoded CSI measurement data to obtain an adapted CSI measurement data; and
transmitting the adapted CSI measurement data to a second computing device.

2. The method of claim 1, wherein the ML model comprises a structural causal model, SCM.

3. The method of claim 1, wherein the ML model models the CSI measurement data as a function of the plurality of specific parameters and the plurality of general parameters.

4. The method of claim 3, wherein the ML model comprises a directed acyclic graph comprising a plurality of nodes that correspond to the CSI measurement data and a plurality of directed edges that account for a causal parent-child relationship.

5. The method of claim 1, wherein the obtaining comprises at least one of (i) detecting the incorrect reporting of CSI, and (ii) receiving a message from the second computing device comprising the incorrect reporting of CSI.

6. The method of claim 1, wherein the plurality of general parameters comprise a plurality of at least one or more of (i) a speed of the first computing device, (ii) a location of the first computing device, (iii) a direction of movement of the first computing device, (iv) a line-of-sight or a non-line-of-sight propagation of a signal between the first computing device and the second computing device, (v) a spatial channel correlation, (vi) one or more sub-carrier frequencies, (vii) an environmental condition, (viii) an available bandwidth, and (ix) a current state of the first computing device.

7. The method of claim 1, wherein the plurality of specific parameters comprise a plurality of at least one or more of (i) a measurement of perceived interference, (ii) a threshold for the first computing device for a particular vendor, (iii) a threshold for the second computing device for a particular vendor, (iv) a power available at the first computing device, (v) a nominal power parameter of the second computing device, (vi) an input power to the second computing device, and (vii) a specified power class for the first computing device.

8. The method of claim 1, further comprising:
building the ML model using a graph neural network, GNN, the plurality of specific parameters, the plurality of general parameters, and CSI data, wherein the built ML model models how a distribution of the CSI measurement data changes with changes in the specific and general parameters.

9. The method of claim 8, wherein the building comprises:
encoding the plurality of specific parameters and the plurality of general parameters, respectively;
inputting to the GNN (i) the encoded plurality of specific parameters as a tensor, (ii) the encoded plurality of general parameters as a tensor, and (iii) the CSI data; and
training the GNN with an adaptive algorithm and an error metric, wherein the trained GNN captures causal relationships between the plurality of specific parameters, the plurality of general parameters, and the CSI data.

10. The method of claim 1, wherein the ML model is trained in a federated learning setting.

11. The method of claim 1, wherein the first computing device comprises a user equipment, UE, and the second computing device comprises a network node.

12. A computer-implemented method performed by a second computing device for decoding causally encoded channel state information, the method comprising:
receiving an adapted channel state information, CSI, data from a first computing device, wherein the adapted CSI data was output from a machine learning, ML, model for CSI reporting comprising causal relationships among parameter data comprising a plurality of specific parameters and a plurality of general parameters and a measurement of CSI data;
decoding the adapted CSI measurement data to obtain decoded CSI; and
using the decoded CSI for a resource allocation.

13. A computer-implemented method performed by a second computing device for causal encoding and decoding of channel state information, CSI, the method comprising:
detecting an incorrect reporting of channel state information, CSI, for a first computing device;
retrieving parameter data comprising a plurality of specific parameters and a plurality of general parameters;
obtaining a measurement of CSI data from the first computing device;
activating a machine learning, ML, model for CSI reporting, the ML model comprising causal relationships among the parameter data and the measured CSI data;
encoding the measurement CSI data to obtain encoded CSI measurement data; and
applying the ML model to the parameter data and the encoded CSI measurement data to obtain an adapted CSI measurement data.

14. The method of claim 13, further comprising:
decoding adapted CSI measurement data to obtain decoded CSI; and
using the decoded CSI for a resource allocation.

15. The method of claim 13, wherein the ML model comprises a structural causal model, SCM.

16. The method of claim 13, wherein the ML model models the CSI measurement data as a function of the plurality of specific parameters and the plurality of general parameters.

17. The method of claim 16, wherein the ML model comprises a directed acyclic graph comprising a plurality of nodes that correspond to the CSI measurement data and a plurality of directed edges that account for a causal parent-child relationship between the CSI measurement data and the parameter data.

18. The method of claim 13, wherein the plurality of general parameters comprise a plurality of at least one or more of (i) a speed of the first computing device, (ii) a line-of-sight or a non-line-of-sight propagation of a signal between the first computing device and the second computing device, (iii) a spatial channel correlation, (iv) one or more sub-carrier frequencies, (v) an environmental condition, an available bandwidth, and (vii) a current state of the first computing device.

19. The method of claim 13, wherein the plurality of specific parameters comprise a plurality of at least one or more of (i) a measurement of perceived interference, (ii) a threshold for the first computing device for a particular vendor, (iii) a threshold for the second computing device for a particular vendor, (iv) a power available at the first computing device, (v) a nominal power parameter of the second computing device, (vi) an input power to the second computing device, and (vii) a specified power class for the first computing device.

20. The method of claim 13, further comprising: building the ML model using a graph neural network, GNN, the plurality of specific parameters, the plurality of general parameters, and CSI data, wherein the built ML model models how a distribution of the CSI measurement data changes with changes in the specific and general parameters.

21-43. (canceled)
